(19) United States
(12) Patent Application Publication
(10) Pub. No.: US 2011/0291681 A1
(43) Pub. Date: Dec. 1, 2011

(54) SEMICONDUCTOR APPARATUS

(75) Inventors: Sang Mook OH, Ichon-shi (KR); Kee Teok Park, Ichon-shi (KR)

(73) Assignee: Hynix Semiconductor Inc., Inchon-shi (KR)

(21) Appl. No.: 12/970,368

(22) Filed: Dec. 16, 2010

(30) Foreign Application Priority Data
May 31, 2010 (KR) 10-2010-0051291

(51) Int. Cl. G01R 1/067; G01R 31/26

(52) U.S. Cl. 324/754.01; 324/762.01

(57) ABSTRACT

A semiconductor apparatus includes: a first power line coupled to a first power transfer pad; a second power line coupled to a second power transfer pad; and a test option unit coupled to the first and second power lines and configured to couple the first and second power lines.

### CROSS-REFERENCES TO RELATED APPLICATION

The present application claims priority under 35 U.S.C. §119(a) to Korean Application No. 10-2010-0051291, filed on May 31, 2010, in the Korean Intellectual Property Office, which is incorporated herein by reference in its entirety as if set forth in full.

### BACKGROUND

1. Technical Field

The present invention relates to a semiconductor apparatus, and more particularly, to power supply of a semiconductor apparatus.

2. Related Art

During a manufacturing process of a semiconductor apparatus, in particular, a semiconductor memory apparatus, a probe test is performed to make sure that cells of the semiconductor memory apparatus at a wafer level normally perform a read/write operation. In the probe test, probe card pins are coupled to power pads of the semiconductor memory apparatus at a wafer level respectively, and power is then supplied to determine an input/output result for the cells through a read/output command.

When the manufacturing process is completed, the semiconductor memory apparatus is coupled to an external application to receive power. However, since the stability of power received from the external application is limited, the semiconductor memory apparatus includes circuits which receive power separately due to power noise and stability. Examples of circuits which receive power separately may include a circuit for outputting data. The circuit for outputting data receives an output power supply voltage and an output ground voltage separately to stabilize the characteristics of output data. Furthermore, a delay locked loop (DLL) circuit related to timing of a clock signal receives a DLL power supply voltage and a DLL ground voltage separately to stably operate the DLL circuit. Furthermore, general circuits use a general power supply voltage and a general ground voltage.

The probe test is performed at a wafer level. A probe card includes a plurality of probe pins which are connected to a plurality of chips on a wafer to supply power. In order to reduce the process time of a probe test, multiple chips on the wafer are simultaneously tested. Depending on the number of probe pins in the probe card, which are connected to pads of the chips, the number of chips to be tested at the same time may differ. Therefore, as the number of probe pins to be coupled to one chip decreases, the number of chips to be tested at the same time increases, and the process time of the probe test is reduced. Furthermore, as the degree of integration in semiconductor memory apparatus increases, the distances between each chip are reduced, and the distances between each probe pin of the probe card are also reduced. Accordingly, there are difficulties in manufacturing a probe card and performing a probe test.

FIG. 1 is a circuit diagram of a conventional semiconductor apparatus. The semiconductor apparatus of FIG. 1 includes a general power supply voltage line (VDD power line) coupled to a general power supply voltage pad (VDD pad) and a DLL power supply voltage line (VDLL power line) coupled to a DLL power supply voltage pad (VDLL pad). As described above, the VDLL power line is a power line for supplying power to DLL circuits, and the VDD power line is a power line for supply power to general circuits excluding the DLL circuits and a data output circuit. Since the characteristics of DLL circuits are vulnerable to power noise, the VDLL power line and a DLL ground voltage line (not illustrated) are separately provided and used. Accordingly, the semiconductor apparatus includes the VDD pad for supplying power to the VDD power line and the VDLL pad for supplying power to the VDLL power line. During a probe test, the semiconductor apparatus illustrated in FIG. 1 couples probe pins to the VDD pad and the VDLL pad, respectively, and receives power.

### SUMMARY

In one aspect of the present invention, a semiconductor apparatus includes: a first power line coupled to a first power transfer pad; a second power line coupled to a second power transfer pad; and a test option unit coupled to the first and second power lines and configured to couple the first and second power lines.

### BRIEF DESCRIPTION OF THE DRAWINGS

Features, aspects, and embodiments are described in conjunction with the attached drawings, in which:

FIG. 1 is a circuit diagram of a conventional semiconductor apparatus;

FIG. 2 is a schematic block diagram of a semiconductor apparatus according to one embodiment; and

FIG. 3 is a circuit diagram illustrating one example of the semiconductor apparatus of FIG. 2.

### DETAILED DESCRIPTION

Hereinafter, a semiconductor apparatus according to the present invention will be described below with reference to the accompanying drawings through exemplary embodiments.

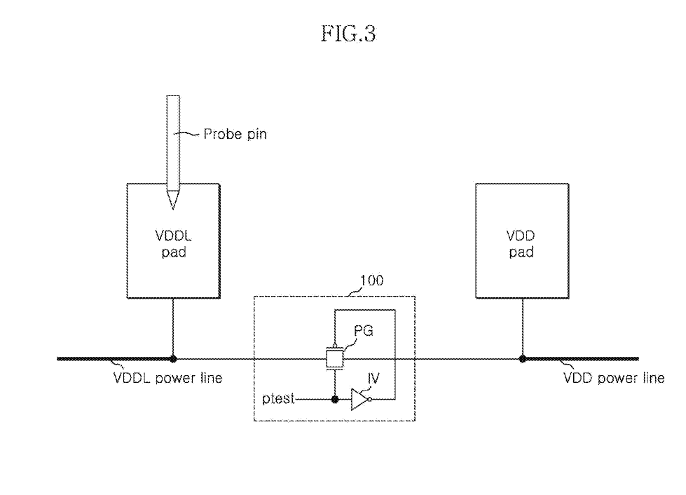

FIG. 2 is a schematic block diagram of a semiconductor apparatus according to one embodiment of the present invention.

The type of power used in a semiconductor apparatus, in particular, a semiconductor memory apparatus, may be classified as general power, DLL power, output power and so on. That is because after the semiconductor memory apparatus is manufactured, the semiconductor memory apparatus receives power from an external application having limited power stability. During a probe test, however, the semiconductor memory apparatus receives power from a probe test equipment. The power supplied by the probe test equipment is more stable than the power supplied from an external application.

The probe test refers to a process of testing whether or not cells of a semiconductor memory apparatus at a wafer level is capable of performing a read/write operation, and is performed by inputting and outputting relatively simple data patterns. Accordingly, although power supplied to the semiconductor memory apparatus is more unstable than the power supplied from an external application after manufacturing is completed, the probe test may be performed.

The embodiment of the present invention has been derived from the principle that the power supplied by the probe test equipment is more stable than the power supplied from an external application and the probe test may still be performed although the semiconductor memory apparatus receives power which is more unstable than the power supplied from an external application.

The semiconductor apparatus illustrated in FIG. 2 includes a first power line coupled to a first power transfer pad, a second power is line coupled to a second power transfer pad, and a test option unit 100 coupled to the first and second power lines and configured to couple the first and second power lines or block the coupling between the first and second power lines.

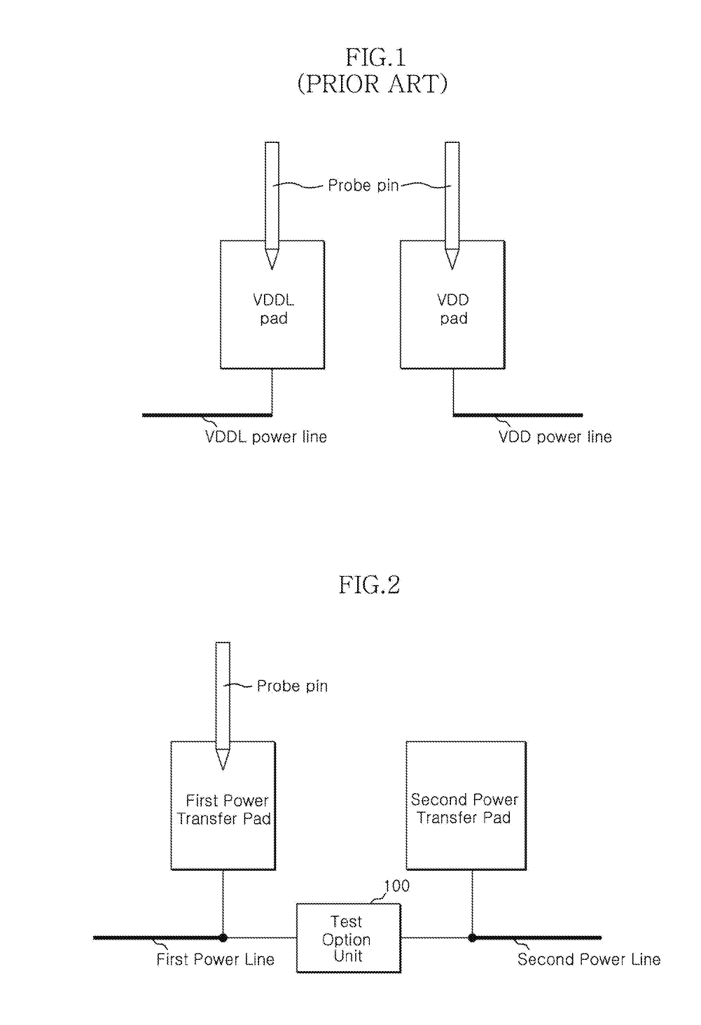

Since the test option unit 100 may couple the first and second power lines or block the coupling between the first and second power lines, the semiconductor apparatus according to the embodiment may transfer power supplied through the first power transfer pad to the second power line. This may work as an advantage in a probe test of the semiconductor memory apparatus. In the semiconductor memory apparatus illustrated in FIG. 1, the probe pins should be coupled to the VDLL pad and the VDD pad, respectively, in order to supply power to the VDD power line and the VDLL power line. In the semiconductor apparatus of FIG. 2, however, when a probe pin is coupled only to the first power transfer pad to supply power, the power may still be supplied to the second power transfer pad, even though a probe pin is not coupled to the second power transfer pad. As described above, the number of chips to be tested at the same time is determined by the number of probe pins coupled to each semiconductor memory chip. Therefore, the semiconductor apparatus according to the embodiment may reduce the test time and cost of the probe test, which makes it possible to increase price competitiveness.

A power pad is typically provided for each type of power. More specifically, one power pad is provided for each of a general is power supply/ground voltage, an output power supply/ground voltage, and a DLL power supply/ground voltage. However, a plurality of power pads may be provided for the same type of power, for example, an output power supply voltage, depending on the semiconductor apparatus. The embodiment of the present invention may be applied identically to such cases as well.

FIG. 3 is a circuit diagram illustrating one example of the semiconductor apparatus of FIG. 2.

The semiconductor apparatus illustrated in FIG. 3 is configured in such a manner that a DLL power supply voltage line (VDLL power line) is used as the first power line, a DLL power supply voltage pad (VDLL pad) is used as the first power transfer pad, a general power supply voltage line (VDD power line) is used as the second power line, and a general power supply voltage pad (VDD pad) is used as the second power transfer pad.

The test option unit 100 illustrated in FIG. 3 is configured to couple the first and second power lines or block the coupling between the first and second power lines in response to a probe test signal ptest. The test option unit 100 includes a pass gate PG and an inverter IV. The inverter IV is configured to receive and invert the probe test signal ptest and output the inverted probe test signal. The pass gate PG is coupled between the first and second power lines and configured to receive the probe test signal ptest and the inverted probe test signal ptest through NMOS and PMOS terminals thereof, respectively. Accordingly, when the probe test signal ptest is activated, the test option unit 100 couples the first and second power lines, and when the probe test signal ptest is deactivated, the test option unit 100 blocks the coupling between the first and second power lines. The probe signal may include a test mode signal. The semiconductor apparatus illustrated in FIG. 3 activates the probe test signal ptest and couples the first and second power lines, during a probe test. Accordingly, although a probe pin is coupled only to the first power transfer pad, power may be supplied to both of the first and second power lines. Furthermore, after the probe test, the probe test signal is fixed to a deactivated state. Then, when an external application is coupled to the semiconductor apparatus after manufacturing is completed, the semiconductor apparatus may perform a normal operation by receiving power through the first and second power transfer pads.

As described above, the test option unit 100 illustrated in FIG. 3 includes the pass gate PG and the inverter IV. Furthermore, the test option unit 100 may include an NMOS transistor (not illustrated) configured to receive the probe test signal ptest. Furthermore, the test option unit 100 may include a PMOS transistor (not illustrated) configured to receive the inverted signal of the probe test signal ptest. Furthermore, the test option unit 100 may include a fuse option (not illustrated). When the test option unit 100 includes the fuse option, there is an advantage in that the probe test signal ptest is not necessary.

The first and second power lines may correspond to all is power lines, as long as a problem does not occur in the operation of the semiconductor apparatus. The semiconductor apparatus according to the embodiment may be configured by using general power supply voltage lines, output power supply voltage lines, DLL power supply voltage lines, general ground voltage lines, output ground voltage lines, or DLL ground voltage lines as the first and second power lines.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising:
a first power line coupled to a first power transfer pad;
a second power line coupled to a second power transfer pad; and
a test option unit coupled to the first and second power lines and configured to couple the first and second power lines.

2. The semiconductor apparatus according to claim 1, wherein the first power line comprises any one of a general power supply voltage line, a general ground voltage line, an output power supply voltage line, an output ground voltage line, a delay locked loop (DLL) power supply voltage line, and a DLL ground voltage line.

3. The semiconductor apparatus according to claim 1, wherein the second power line comprises any one of a general power supply voltage line, a general ground voltage line, an output power supply voltage line, an output ground voltage line, a DLL power supply voltage line, and a DLL ground voltage line.

4. The semiconductor apparatus according to claim 1, wherein the test option unit comprises a pass gate configured to be activated in responses to a probe test signal.

5. The semiconductor apparatus according to claim 1, wherein the test option unit comprises a transistor configured to be activated in response a probe test signal.

6. The semiconductor apparatus according to claim 1, wherein the test option unit comprises a fuse.

7. The semiconductor apparatus according to claim 1, wherein the test option unit is further configured to block the coupling between the first and second power lines.
